(19) United States
(12) Patent Application Publication
(10) Pub. No.: US 2013/0009274 A1
(43) Pub. Date: Jan. 10, 2013

(54) MEMORY HAVING THREE-DIMENSIONAL STRUCTURE AND MANUFACTURING METHOD THEREOF

(75) Inventors: Seungbeck Lee, Gyeonggi-do (KR); Seulki Oh, Seoul (KR); Junhyuk Lee, Seoul (KR)

(73) Assignee: Industry-University Cooperation Foundation Hanyang University, Seoul (KR)

(21) Appl. No.: 13/520,025

(22) PCT Filed: Dec. 29, 2010
(86) PCT No.: PCT/KR10/09490

§ 371 Date: Sep. 21, 2012

(30) Foreign Application Priority Data
Dec. 31, 2009 (KR) 10-2009-0135316
Jun. 9, 2010 (KR) 10-2010-0054301

(51) Int. Cl. H01L 29/02; H01L 21/20; H01L 21/28

(52) U.S. Cl. 257/499; 438/586; 438/478; 257/E29.002; 257/E21.209; 257/E21.09

(57) ABSTRACT

Provided are a memory having a 3-dimensional structure and a method of fabricating the same, by which high integration density can be obtained. A contact region connected to a word line is formed to extend from a cell region in a first direction. A plurality of step difference layers constituting the contact region are formed to have step differences in a second direction different from the first direction. Also, provided is a method of fabricating a nonvolatile memory by which step differences are formed in a direction substantially perpendicular to a direction in which active regions are aligned. An insulating layer and etching layers are sequentially formed. By performing a selective etching process and pattern transfer, step differences are formed in a direction perpendicular to a direction in which multilayered active layers are disposed. Furthermore, the etching layers are removed using a wet etching process, and an oxide-nitride-oxide (ONO) layer and conductive layers are provided on the multilayered active layers having exposed side surfaces to form cell transistors. Thus, a memory having a high integration density is fabricated.

### TECHNICAL FIELD

The present invention relates to a memory, and more particularly, to a memory having a 3-dimensional structure and a method of fabricating the same.

### BACKGROUND ART

A flash memory, which is a typical nonvolatile memory device, operates based on a mechanism by which a state is changed by trapping and erasing charges. In recent years, a technique of improving integration density has been developed by conducting research into a device structure capable of proportionately reducing unit cells and embodying multi-bits.

In particular, a technique of improving the integration density of a flash memory by proportional reduction brings about a short channel effect, punch-through, and deficiency in the margin of a sensing current. These phenomena naturally occur due to a reduction in the channel length of unit cells. To overcome these problems, a technique of 3-dimensionally embodying a structure of a flash memory has been developed.

FIG. 1 is a perspective view of a structure of a conventional flash memory.

Referring to FIG. 1, the conventional flash memory is divided into a cell region 100 and a contact region 200.

The cell region 100 has sequentially stacked electrode layers 121, 123, 125, and 127 and insulating layers 110, 112, 114, and 116. A gate structure 130 is formed through the stacked electrode layers 121, 123, 125, and 127 and the insulating layers 110, 112, 114, and 116. The gate structure 130 has a central portion formed of polycrystalline silicon (poly-Si) and an oxide-nitride-oxide (ONO) structure formed toward an outer circumferential surface thereof. That is, a tunneling oxide layer, a charge trap layer, and a blocking insulating layer are sequentially disposed outside the poly-Si. Poly-Si surrounded with the ONO structure operates as an active region or a channel region in a cell transistor of the flash memory.

Selection transistors 140 are disposed on the plurality of stacked electrode layers 121, 123, 125, and 127 and the plurality of stacked insulating layers 110, 112, 114, and 116. Each of the selection transistors 140 includes a selection electrode layer 142 extending in a first direction. The selection electrode layer 142 is disposed apart from adjacent selection electrode layers in a second direction. Also, a gate structure 144 may be formed through the selection electrode layer 142 and electrically connected to the gate structure 130 formed through the electrode layers 121, 123, 125, and 127 and the insulating layers 110, 112, 114, and 116. However, the gate structure 144 formed through the selection electrode layer 142 may include only poly-Si and a gate oxide layer. Accordingly, poly-Si of the gate structure 144 formed through the selection electrode layer 142 operates as an active region or a channel region of a semiconductor, and the selection electrode layer 142 operates as a gate electrode. Furthermore, bit lines 150 are disposed on the gate structure 144 formed through the selection electrode layer 142. The bit lines 150 are formed to extend in the second direction and are spaced apart from adjacent bit lines in the first direction.

The contact region 200 is connected to the cell region 100 and forms a stack structure integrally formed with the electrode layers 121, 123, 125, and 127 and the insulating layers 110, 112, 114, and 116 of the cell region 100. That is, the electrode layers 121, 123, 125, and 127 and the insulating layers 110, 112, 114, and 116 extend to the contact region 200 across the cell region 100. Also, the electrode layers 121, 123, 125, and 127 and the insulating layers 110, 112, 114, and 116 have step differences with smaller areas toward an upper portion of the cell region 100. However, the first insulating layer 110 and the first electrode layer 121 of FIG. 1 may have the same profile, and each of the remaining electrode layers and the corresponding insulating layer may have the same profile.

Since one side of the contact region 200 is integrally formed with the electrode layers 121, 123, 125, and 127 and the insulating layers 110, 112, 114, and 116 of the cell region 100, the one side of the contact region 200 is connected to the cell region 100. The other side of the contact region 200 has a different step difference according to height and is structured to expose portions of the electrode layers 121, 123, 125, and 127.

Although not shown, an interlayer insulating layer (not shown) is wholly coated on the electrode layer, the insulating layer, or the exposed structure. The electrode layers 121, 123, 125, and 127 protruding from the contact region 200 are connected to plugs 210. The plugs 210 are formed through the coated interlayer insulating layer. Also, upper portions of the plugs 210 are connected to word lines 220. The word lines 220 extend in the first direction and are spaced apart from one another in the second direction.

The above-described conventional art relates to a Bit-Cost Scalable (BiCS) structure. In the BiCS structure, the plugs 210 in contact with the word lines 220 are formed on the plurality of electrode layers 121, 123, 125, and 127 having step differences. The electrode layers 110, 112, 114, and 116 are technically embodied by coating and etching photoresist and transferring a pattern using a process of downscaling the remaining photoresist. However, the electrode layers 121, 123, 125, and 127 constituting the contact region 200 have step differences parallel to a direction in which the electrode layers 121, 123, 125, and 127 extend from the cell region 100. That is, electrode layers protruding from the cell region 100 extend to the electrode layers of the contact region 200 and form step differences with respect to other electrode layers 121, 123, 125, and 127 disposed thereunder or thereon in the extending direction.

In particular, to prevent occurrence of a short circuit between the plugs 210 interposed between the word lines 220 and the electrode layers 121, 123, 125, and 127, predetermined step differences should be made downward. Accordingly, the electrode layers 121, 123, 125, 127 tend to widen toward a lower end of the structure.

Accordingly, when the number of the electrode layers 121, 123, 125, and 127 operating as the control gates of the flash memory increases, the area of the overall memory increases greatly, thereby causing a loss of integration density.

### DISCLOSURE

### Technical Problem

The present invention is directed to a flash memory having a 3-dimensional structure and capable of embodying high integration density.

Also, the present invention is directed to a method of fabricating the above-described flash memory.

Furthermore, the present invention is directed to a method of fabricating a memory, by which a 3-dimensional structure may be embodied to attain high integration density.

### Technical Solution

One aspect of the present invention provides a flash memory including a cell region having insulating layers and electrode layers alternately formed, the cell region having multilayered plugs formed through the insulating layers and the electrode layers, and a contact region extending from the cell region in a first direction, the contact region having a step difference in a second direction perpendicular to the first direction.

Also, the one aspect of the present invention is obtained by providing a flash memory including a contact region connected to a cell region including a cell transistor and electrically connected to a word line, wherein the contact region includes a plurality of step difference layers having step differences formed in a different direction from a direction in which the cell region and the contact region are disposed.

Another aspect of the present invention provides a method of fabricating a flash memory, including sequentially stacking insulating layers and electrode layers and forming multilayered plugs through the insulating layers and the electrode layers, forming a selective insulating layer and a selective conductive layer on an uppermost electrode layer and forming string plugs through the selective insulating layer and the selective conductive layer to be electrically connected to the multilayered plugs, forming a string selection region by selectively etching the selective insulating layer and the selective conductive layer and defining a cell region and a contact region extending in a first direction, and forming a plurality of step difference layers by performing sequential pattern transfer on the contact region, the plurality of step difference layers having step differences in a second direction perpendicular to the first direction.

Another aspect of the present invention provides a method of fabricating a memory, including alternately forming preliminary etching layers and insulating layers, sequentially forming a selective insulating layer, a selective etching layer, and a sacrificial insulating layer on an uppermost preliminary etching layer, forming multilayered active layers through the preliminary etching layers, the insulating layers, the selective insulating layer, the selective etching layer, and the sacrificial insulating layer, the multilayered active layers disposed in a first direction, defining a contact region and a cell region having the multilayered active layers, forming a step difference in a second direction perpendicular to the first direction by performing pattern transfer on the contact region, forming a plurality of string regions by selectively etching the cell region after performing the pattern transfer, the plurality of string regions extending in the first direction, and removing the selective etching layer and the preliminary etching layers and forming an oxide-nitride-oxide (ONO) layer and conductive layers.

Also, the other aspect of the present invention is obtained by providing a method of fabricating a memory, including alternately forming preliminary etching layers and insulating layers, sequentially forming a selective insulating layer, a selective etching layer, and a sacrificial insulating layer on an uppermost preliminary etching layer, forming multilayered active layers through the preliminary etching layers, the insulating layers, the selective insulating layer, the selective etching layer, and the sacrificial insulating layer, the multilayered active layers disposed in a first direction, forming string regions by etching regions in which the multilayered active layers are formed, in the first direction, removing the selective etching layer and the preliminary etching layers and forming an ONO layer and conductive layers on side surfaces of the multilayered active layers, defining a contact region and a cell region including the regions in which the multilayered active regions are formed and which are etched in the first direction, forming step differences in a second direction perpendicular to the first direction by performing pattern transfer on the contact region, and removing the exposed sacrificial insulating layer using a blanket etching process and removing the selective insulating layer and the insulating layers exposed on the step differences to expose the conductive layers.

### Advantageous Effects

According to the present invention, a step difference of a contact region connected to a word line is formed in a different direction from a direction in which the contact region extends from a cell region. That is, the step difference is formed in a second direction substantially perpendicular to a first direction in which the contact region extends. Also, a plurality of step difference groups are formed, thereby efficiently enabling complicated contact functions. As a result, a device can be highly integrated.

Furthermore, according to the present invention, an ONO layer and a conductive layer are formed on side surfaces of a multiple active layer that are exposed by removing a selective etching layer and preliminary etching layers. Thus, a cell transistor is embodied. Also, the conductive layer is formed of a metal material and controls operations of the cell transistor. One multilayered active layer includes a plurality of cell transistors, thereby enabling fabrication of a highly integrated nonvolatile memory device.

### DESCRIPTION OF DRAWINGS

FIG. 1 is a perspective view of a structure of a conventional flash memory.

FIG. 2 is a perspective view of a flash memory according to a first exemplary embodiment of the present invention.

FIGS. 3 through 9 are perspective views illustrating a method of fabricating the flash memory shown in FIG. 2, according to the present embodiment.

FIGS. 10 through 13 are perspective views illustrating another method of fabricating the flash memory shown in FIG. 2, according to the first embodiment of the present invention.

FIG. 14 is a perspective view of a flash memory according to a second exemplary embodiment of the present invention.

FIGS. 15 through 19 are perspective views illustrating a method of fabricating the flash memory shown in FIG. 2, according to the second embodiment.

FIGS. 20 through 33 are perspective views illustrating a method of fabricating a memory having a 3-dimensional structure according to a third exemplary embodiment of the present invention.

FIGS. 34 through 41 are perspective views illustrating a method of fabricating a memory according to a fourth exemplary embodiment of the present invention.

### MODE FOR INVENTION

While the present invention is susceptible to various modifications and may take on various alternative forms, specific embodiments thereof are shown by way of example in the drawings and will herein be described in detail. It should be understood, however, that there is no intent to limit the invention to the particular forms disclosed. On the contrary, the present invention is to cover all modifications, equivalents, and alternatives falling within the spirit and scope of the claims. In the drawings, similar reference numerals are used to denote similar elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present invention will be described more fully hereinafter with reference to the accompanying drawings, in which exemplary embodiments of the invention are shown.

### Embodiment 1

FIG. 2 is a perspective view of a flash memory according to a first exemplary embodiment of the present invention.

Referring to FIG. 2, the flash memory according to the present embodiment has a cell region 300, a contact region 400, a bit line interconnection region 500, and a word line interconnection region 600.

The cell region 100 includes cell transistors of the flash memory. To constitute the cell transistors, a plurality of insulating layers 310, 312, 314, and 316, a plurality of electrode layers 321, 323, 325, and 327, and plugs 330 formed through the insulating layers 310, 312, 314, and 316 and the electrode layers 321, 323, 325, and 327 are included.

The insulating layers 310, 312, 314, and 316 may be formed of any insulating material. Also, the electrode layers 321, 323, 325, and 327 may be formed of any conductive material but are preferably formed of a metal material.

To begin with, the plurality of insulating layers 310, 312, 314, and 316 and the plurality of electrode layers 321, 323, 325, and 327 are alternately stacked, and one insulating layer and one electrode layer form a pair. Thus, a first electrode layer 321 having the same profile as the first insulating layer 310 is disposed on a first insulating layer 310, and a second insulating layer 321 and a second electrode layer 323 are disposed on the first electrode layer 321 and form a pair.

Pairs of insulating layers 310, 312, 314, and 316 and electrode layers 321, 323, 325, and 327 are sequentially disposed, and the number of stacked pairs of insulating layers 310, 312, 314, and 316 and electrode layers 321, 323, 325, and 327 is arbitrarily determined according to a desired storage capacity.

Multilayered plugs 330 are disposed through the insulating layers 310, 312, 314, and 316 and electrode layers 321, 323, 325, and 327. Each of the multilayered plugs 330 has poly-Si and an ONO structure from the center thereof toward an outer circumferential surface thereof. Thus, poly-Si is disposed in the center of each of the multilayered plugs 330, and the ONO structure is formed in an outer region thereof. Accordingly, poly-Si disposed in the center of each of the multi-layered plugs 330 functions as an active region or a channel region of the corresponding cell transistor, and charge trap and erase operations are enabled by the ONO structure disposed in the outer region of each of the multi-layered plugs 330. Also, the electrode layers 321, 323, 325, and 327 function as control gates.

The contact region 400 extends in a first direction and has a plurality of step difference layers 430, 440, 450, and 460. The step difference layers 430, 440, 450, and 460 include the pairs of insulating layers 310, 312, 314, and 316 and electrode layers 321, 323, 325, and 327, respectively, and have step differences in a second direction different from the first direction. In particular, the second direction is preferably perpendicular to the first direction.

That is, each of the step difference layers 430, 440, 450, and 460 of the contact region 400 includes the corresponding one of the pairs of insulating layers 310, 312, 314, and 316 and electrode layers 321, 323, 325, and 327, which has the same profile, and extends in the first direction from the cell region 300. The insulating layers 310, 312, 314, and 316 and the electrode layers 321, 323, 325, and 327 form respective pairs, which have step differences with respect to one another in the second direction.

For example, the first insulating layer 310 and the first electrode layer 321, which constitute a first step difference layer 430, have the same profile.

A second step difference layer 440 is disposed on the first step difference layer 430. The second step difference layer 440 has a shape with a smaller size than the first step difference layer 430 and has a step difference with respect to the first step difference layer 430 to expose a portion of a top surface of the first step difference layer 430. Also, the second step difference layer 440 includes the second insulating layer 312 and the second electrode layer 323, which have the same profile.

The above-described construction of the second step difference layer 440 is applied likewise to third and fourth step layers 450 and 460. Also, it would be apparent to one skilled in the art that a larger number of step difference layers than four may be included according to embodiments.

The step difference layers 430, 440, 450, and 460 disclosed in the present embodiment are integrally formed with the insulating layers 310, 312, 314, and 316 and electrode layers 321, 323, 325, and 327 of the cell region 300 and have step differences in a perpendicular direction to a direction in which the step difference layers 430, 440, 450, and 460 extend from the cell region 300. That is, when the contact region 400 extends in the first direction from the cell region 300, the step difference layers 430, 440, 450, and 460 constituting the contact region 400 are configured to have sequential step differences in the second direction perpendicular to the first direction. Accordingly, regions of the step difference layers 430, 440, 450, and 460 of the contact region 400, which are in contact with the cell region 300, tend to shrink toward an upper region of the contact region 400.

A bit line interconnection region 500 is disposed on the cell region 300.

The bit line interconnection region 500 includes a string selection region 510 and bit lines 530.

The string selection region 510 includes a selective insulating layer 511, a selective conductive layer 513, and string plugs 515.

The selective insulating layer 511 is disposed on the cell region 300, and the selective conductive layer 513 is disposed on the selective insulating layer 511. The selective insulating layer 513 is used to enable electrical insulation between the uppermost conductive layer 327 of the cell region 300 and the selective conductive layer 513. Also, the selective conductive layer 513 may have the same profile as the selective insulating layer 511.

The string plugs 515 are formed through the selective insulating layer 511 and the selective conductive layer 513. Each of the string plugs 515 includes poly-Si disposed in the center thereof and a gate insulating layer disposed in an outer region thereof. Thus, poly-Si of each of the string plugs 515 operates as an active region or a channel region of a string selection transistor, and the selection conductive layer 513 acts as a gate electrode. Also, each of the string plugs 515 is formed through the cell region 400 and connected to the corresponding one of the multilayered plugs 330. In particular, poly-Si formed in a central portion of each of the string plugs 515 is electrically connected to poly-Si formed in a central portion of the corresponding one of the multilayered plugs 330. The string plugs 515 are formed through an interlayer insulating layer (not shown) and connected to the bit lines 530.

The bit lines 530 extend in the second direction and are spaced apart from adjacent bit lines in the first direction. The bit lines 530 are electrically connected to the string plugs 515, and particularly, electrically connected to poly-Si constituting the string plugs 515.

The word line interconnection region 600 includes via plugs 610 and word lines 630.

The via plugs 610 are formed through the interlayer insulating layer and connected to the step difference layers 430, 440, 450, and 460 constituting the contact region 400. In particular, the via plugs 610 are respectively provided on exposed portions of the electrode layers 321, 323, 325, and 327 constituting the step difference layers 430, 440, 450, and 460. Thus, the via plugs 610 are spaced apart from one another in the second direction and have upper portions connected to the word lines 630.

The word lines 630 are electrically connected to the via plugs 610 and extend in the first direction. Also, the word lines 630 are spaced a predetermined distance apart from adjacent word lines 630 in the second direction.

Referring to FIG. 2, at least one layer may be provided under the first insulating layer 310 to make an operation of the flash memory smoother. For example, an additional transistor may be provided under the first insulating layer 310 to control on/off of electric signals transmitted from the multilayered plugs 330.

Furthermore, the cell region 300 and the contact region 400 of FIG. 2 are halved by a trench 650. The trench 650 is preferably filled with the interlayer insulating layer.

The trench 650 halves the plurality of insulating layers 310, 312, 324, and 326 and the plurality of electrode layers 321, 323, 325, and 327.

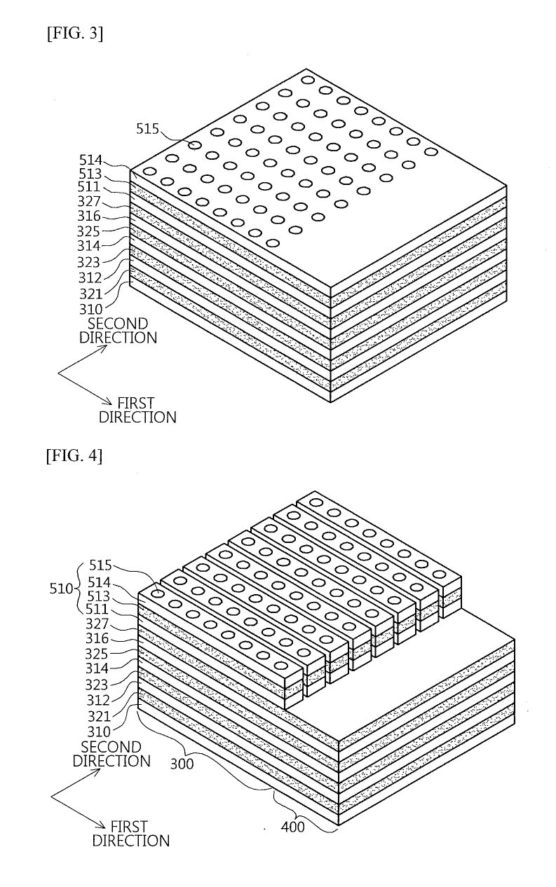

FIGS. 3 through 9 are perspective views illustrating a method of fabricating the flash memory shown in FIG. 2, according to the present embodiment.

Referring to FIG. 3, the insulating layers 310, 312, 314, and 316 and the electrode layers 321, 323, 325, and 327 are sequentially stacked on a substrate. Thereafter, a plurality of holes are formed in the stacked insulating layers 310, 312, 314, and 316 and electrode layers 321, 323, 325, and 327, and multilayered plugs are formed to fill the holes. The multilayered plugs are embodied by growing ONO from sidewalls of the holes and filling the holes with poly-Si.

Subsequently, the selective insulating layer 511 and the selective electrode layer 513 are formed on the uppermost electrode layer. Also, holes are formed in the selective insulating layer 511 and the selective electrode layer 513 to open surfaces of the formed multilayered plugs. The opened holes are filled with a gate insulating layer and poly-Si to form the selective plugs 515. The selective plugs 515 are electrically connected to the formed multilayered plugs, respectively. Also, an additional protection layer 514 may be formed on the selective electrode layer 514 according to embodiments. The protection layer 514 may be formed of any insulating material but is preferably formed of silicon oxide.

Referring to FIG. 4, photoresist is coated and removed from regions other than the string selection region 510 using a patterning process. Subsequently, portions of the selective insulating layer 511 and the selective electrode layer 513 are removed using the remaining pattern as an etch mask. The removal of the selective insulating layer 511 and the selective electrode layer 513 is performed such that the string selection region 510 extending in the first direction is separated from adjacent string selection regions in the second direction. Due to the above-described etching process, a portion of an electrode layer disposed as an uppermost layer in the contact region 400 is opened, and the cell region 300 and the contact region 400 are partitioned.

Furthermore, according to embodiments, during the formation of the separated string selection region 510, a trench may be formed to halve the structure shown in FIG. 4 and open a portion of the substrate. By forming the trench, the cell region and the contact region 400 are halved.

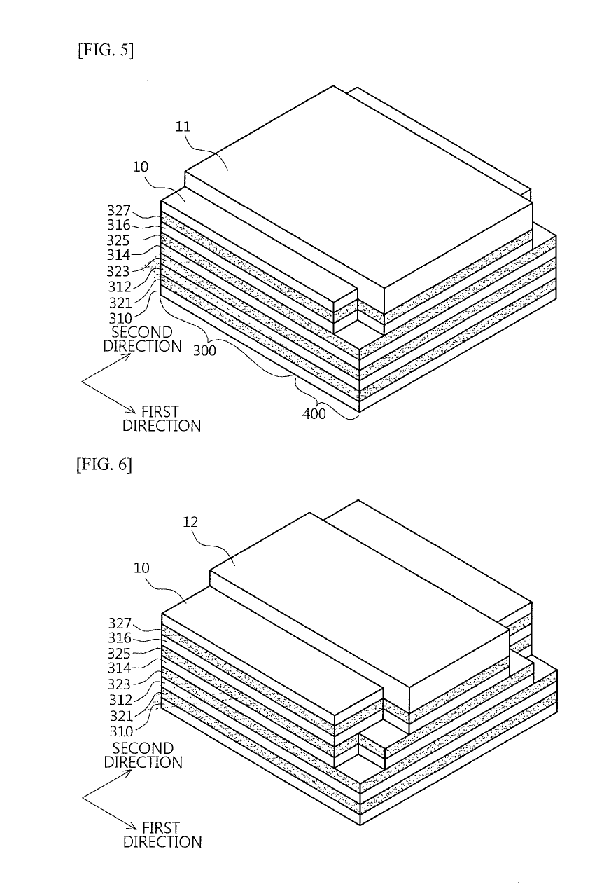

Referring to FIG. 5, the photoresist pattern shown in FIG. 4 is removed.

Thereafter, a hard mask layer 10 is formed to cover the cell region 300, photoresist is coated on the hard mask layer 10, and a first photoresist pattern 11 is formed using an ordinary patterning process or photoresist reduction process. In particular, the photoresist reduction process, which is referred to as photoresist shrink or photoresist slimming, is performed to reduce the size of the formed photoresist. A reduction in the photoresist is attained by exposing the photoresist to a reactive plasma gas. However, the reactive plasma gas may be differently selected according to the composition of a photoresist pattern.

The fourth electrode layer 327 of the contact region 400 may be etched using the sequentially formed first photoresist pattern 11 and hard mask layer 10 as an etch mask. Due to the etching, the fourth electrode layer 327 has the same profile as the first photoresist pattern 11, and a portion of the surface of the fourth insulating layer 316 disposed under the fourth electrode layer 11 is exposed.

Thereafter, the exposed portion of the surface of the fourth insulating layer 316 is etched to expose a partial surface of the third electrode layer 325 disposed under the fourth insulating layer 316. As a result, the fourth electrode layer 327 and the fourth insulating layer 316 have the same profile as the first photoresist pattern 11, and a portion of the surface of the third electrode layer 325 is exposed.

Furthermore, the string selection region 510 formed on the fourth electrode layer 327 is omitted from FIG. 5 for brevity. This is because the aspect of the string selection region 510 is not changed during the fabrication process described with reference to FIGS. 5 through 9. Accordingly, the illustration and description of the string selection region 510 are omitted from FIGS. 5 through 8.

Referring to FIG. 6, a reduction process or a new photolithography process is performed on the first photoresist pattern 11, thereby forming a second photoresist pattern 12. The second photoresist pattern 12 has a reduced shape as compared with the first photoresist pattern 11 in the second direction. By forming the second photoresist pattern 12, a portion of the surface of the fourth electrode layer 327 is exposed. Thereafter, the exposed third and fourth electrode layers 325 and 327 are etched using the second photoresist pattern 12 as an etch mask. Accordingly, the fourth electrode layer 327 has the same profile as the second photoresist pattern 12, and the fourth insulating layer 316 is not etched but remains. The remaining fourth insulating layer 316 acts as an etch mask for the exposed third electrode layer 325. Accordingly, even if the third electrode layer 325 is etched, the third electrode layer 325 has the same profile as the fourth insulating layer 316. That is, the third electrode layer 325 has the same profile as the first photoresist pattern 1. Also, a partial surface of the third insulating layer 314 disposed under the third electrode layer 325 is exposed.

Subsequently, the fourth insulating layer 316 and the third insulating layer 314 exposed by etching are etched using the second photoresist pattern 12 and the third electrode layer 314 as an etch mask. Thus, the fourth insulating layer 316 has the same profile as the second photoresist pattern 12, and the third insulating layer 314 has the same profile as the first photoresist pattern 11.

That is, due to the process of FIG. 6, the third electrode layer 325 and the third insulating layer 314 have the same profile as the first photoresist pattern 11, and the fourth electrode layer 327 and the fourth insulating layer 316 have the same profile as the second photoresist pattern 12. This means that due to the etching, the first photoresist pattern 11 is transferred to an underlying layer and a newly generated photoresist pattern is transferred to an uppermost layer.

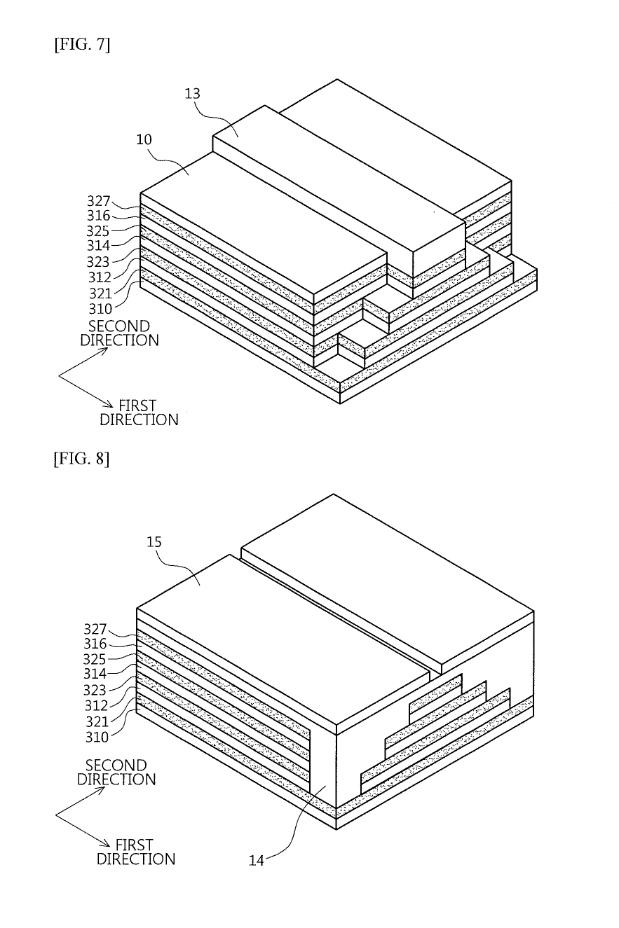

Referring to FIG. 7, a reduction process or a new photoresist process is performed on the second photoresist pattern 12, thereby forming a third photoresist pattern 13.

By forming the third photoresist pattern 13, a portion of the surface of the fourth electrode layer 327 is exposed. Thereafter, the exposed second electrode layer 323, third electrode layer 325, and fourth electrode layer 327 are etched using the third photoresist pattern 13 as an etch mask.

Accordingly, the fourth electrode layer 327 has the same profile as the third photoresist pattern 13, and the fourth insulating layer 316 is not etched but remains. The remaining fourth insulating layer 316 acts as an etch mask for the exposed third electrode layer 325. Accordingly, even if the third electrode layer 325 is etched, the third electrode layer 325 has the same profile as the fourth insulating layer 316. That is, the third electrode layer 325 has the same profile as the second photoresist pattern 12. Also, a partial surface of the third insulating layer 314 disposed under the third electrode layer 325 is exposed. In addition, by etching the second electrode layer 323, a portion of the second insulating layer 312 disposed under the second electrode layer 323 is exposed.

Subsequently, the fourth insulating layer 316, third insulating layer 314, and second insulating layer 312 exposed by etching are etched using the third photoresist pattern 13, the third electrode layer 325, and the second electrode layer 323 as an etch mask. As a result, the fourth insulating layer 316 has the same profile as the third photoresist pattern 13, the third insulating layer 314 has the same profile as the second photoresist pattern 12, and the second insulating layer 312 has the same profile as the first photoresist pattern 11.

As described above, a photoresist pattern is sequentially transferred to underlying layers. When the transfer of a pattern is completed, the first step difference layer 430, the second step difference layer 440, the third step difference layer 450, and the fourth step difference layer 460 are provided from below. Each of the step difference layers 430, 440, 450, and 460 includes an insulating layer and an electrode layer. The insulating layer and the electrode layer constituting one step difference layer have the same profile. The respective step difference layers are configured to expose portions of the electrode layers upward. That is, the respective step difference layers tend to have smaller areas upward.

Referring to FIG. 8, the photoresist pattern and the hard mask layer are removed from the structure shown in FIG. 7. Thereafter, a sacrificial layer is formed to bury the entire structure.

Photoresist is coated on the sacrificial layer, and a photoresist pattern for isolation is formed using an ordinary photolithography process. The photoresist pattern for isolation is configured to halve the formed step difference layers.

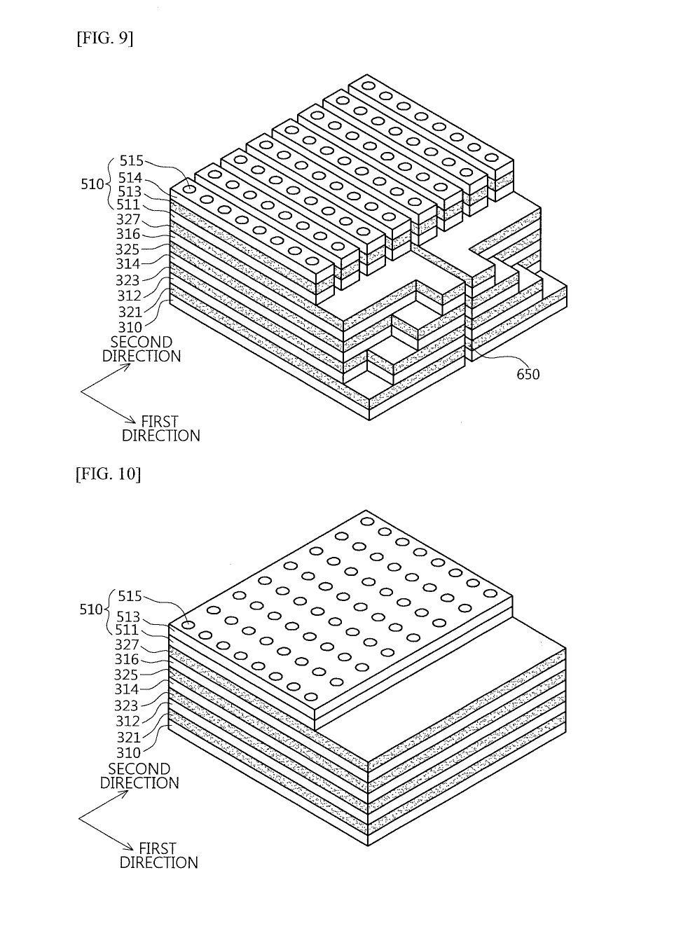

Thereafter, an etching process is performed using the photoresist pattern for isolation as an etch mask, thereby halving the insulating layer and the electrode layer. Due to the above-described process, a structure shown in FIG. 9 is formed.

When a process of halving the structure by forming a trench along with a string selection region is performed as described with reference to FIG. 4, the fabrication process shown in FIGS. 7 and 8 is not required.

FIGS. 10 through 13 are perspective views illustrating another method of fabricating the flash memory shown in FIG. 2, according to the first embodiment of the present invention.

The fabrication steps in FIG. 3 are applied in the same manner prior to the fabrication steps in FIG. 10. Accordingly, insulating layers 310, 312, 314, and 316 and electrode layers 321, 323, 325, and 327 are sequentially formed, and multilayered plugs 330 are formed through the insulating layers 310, 312, 314, and 316 and the electrode layers 321, 323, 325, and 327. The multilayered plugs 330 are embodied by forming an ONO layer on sidewalls of holes and filling the holes with poly-Si.

Also, a selective insulating layer 511 and a selective electrode layer 513 are formed on an uppermost electrode layer, and selective plugs 515 are formed through the selective insulating layer 511 and the selective electrode layer 513 and electrically connected to the multilayered plugs. Furthermore, an additional protection layer 514 may be formed on the selective electrode layer 514 according to embodiments. The protection layer 514 may be formed of any insulating material but is preferably formed of silicon oxide.

Subsequently, referring to FIG. 10, a photoresist pattern is formed using an ordinary photolithography process, and an etching process is performed using the formed photoresist pattern as an etch mask. By performing the etching process, portions of the selective insulating layer 511 and the selective electrode layer 513 are removed. A region from which the selective insulating layer 511 and the selective electrode layer 513 are removed is defined as a contact region 400, and the remaining region is defined as a cell region 300.

That is, the contact region 400 and the cell region 300 are defined through the process described with reference to FIG. 10.

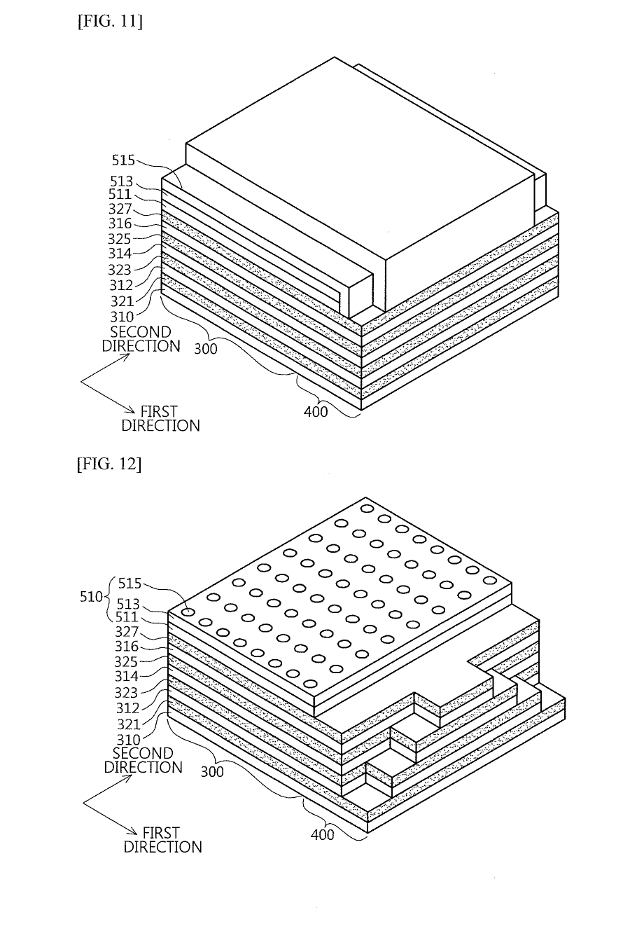

Referring to FIG. 11, a hard mask layer 30 is formed on the remaining selective electrode layer 513 of FIG. 10. The hard mask layer 30 completely shields side surfaces of the selective insulating layer 511 and the selective electrode 513, which are exposed in a front direction, and covers the top of the selective electrode layer 513. Thereafter, a first photoresist pattern 40 having a predetermined width is formed on the hard mask layer 30 and the contact region 400.

Subsequently, an etching process and a process of forming a new photoresist pattern are performed to enable transfer of a pattern. The transfer of the pattern is the same as described in the first embodiment with reference to FIGS. 5 through 7.

Accordingly, to facilitate understanding and avoid a repeated description, a process of forming step differences by transferring a pattern will be omitted here.

By transferring the pattern and removing the photoresist pattern and the hard mask layer, a structure shown in FIG. 12 is formed.

Referring to FIG. 12, a plurality of step difference layers are formed in the contact region 400 and have smaller widths upward. Each of the step difference layers includes an insulating layer and an electrode layer, and a portion of each of the electrode layers is exposed.

Also, a string selection region 510 is provided on the cell region 300. However, the string selection region 510 is not patterned but integrally provided.

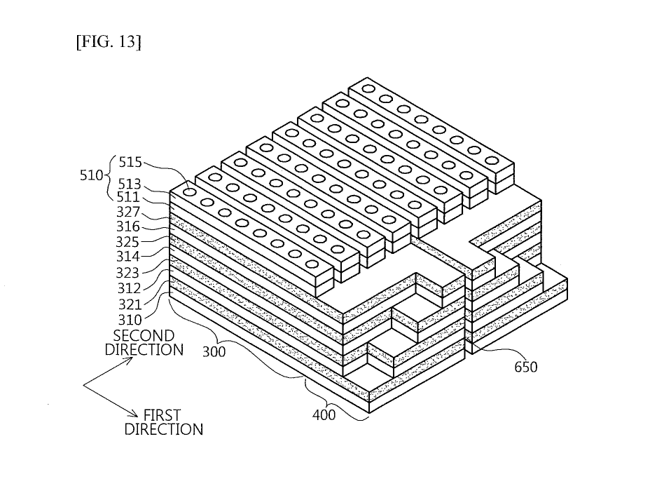

Referring to FIG. 13, a trench 650 is formed using an ordinary photolithography process to halve the cell region 300, the string selection region 510, and the contact region 400. Also, string selection regions, which are patterned by selectively etching the string selection region 510, are formed in regions halved by the trench 650.

Subsequent processes of fabricating the flash memory of FIG. 2 are performed using a conventional known method. That is, an interlayer insulating layer is blanket-coated on the structure of FIG. 9 or FIG. 13, and string plugs and via plugs are formed by forming holes and filling the holes. In addition, the string plugs are electrically connected to bit lines formed using a metal interconnection process, while the via plugs are electrically connected to word lines.

### Embodiment 2

The flash memory obtained according to the above-described first embodiment may be fabricated using a structure in which a contact region has a double terminal.

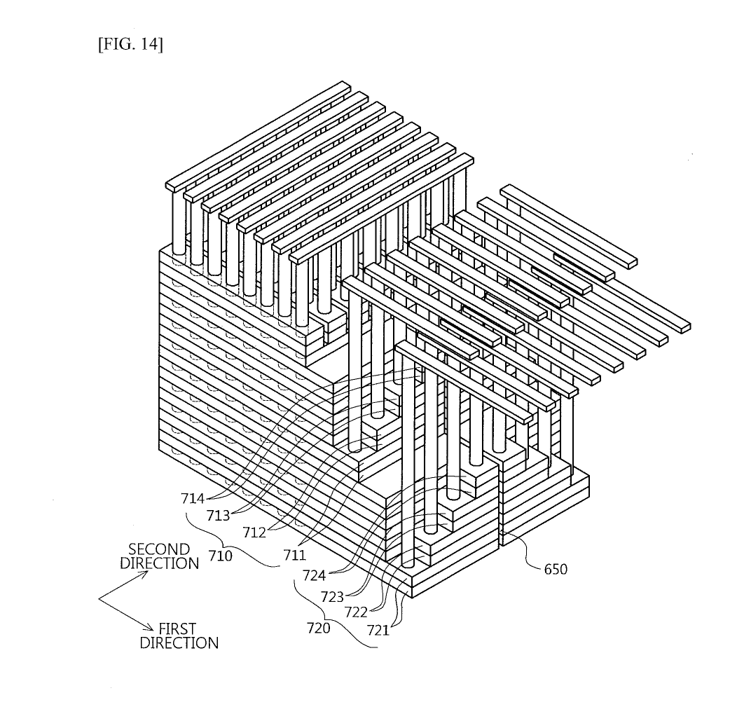

FIG. 14 is a perspective view of a flash memory according to a second exemplary embodiment of the present invention.

Referring to FIG. 14, the flash memory is the same as shown in FIG. 2 except that step difference layers of a contact region 700 include two groups 710 and 720.

That is, the step difference layers include a first step difference group 710 and a second step difference group 720.

The second step difference group 720 is disposed at a lower end of the contact region 700 and protrudes in a first direction.

Also, the first step difference group 710 is disposed over the second step difference group 720 and closer to a cell region than the second step difference group 720. That is, the first step difference group 710 and the second step difference group 720 extend in the first direction from a region in which a cell transistor is formed. The second step difference group 720 disposed below is disposed farther than the first step difference group 710 disposed above.

Accordingly, there is an overall step difference between the first step difference group 710 and the second step difference group 720 in the first direction, and the first step difference group 710 disposed above has an overall smaller area than the second step difference group 720.

Furthermore, step difference layers 711, 712, 713, 714, 721, 722, 723, and 724 constituting the respective step difference groups 710 and 720 are configured to have step differences in a second direction perpendicular to the first direction within the corresponding one of the step difference groups.

FIGS. 15 through 19 are perspective views illustrating a method of fabricating the flash memory shown in FIG. 14, according to the second embodiment of the present invention.

Referring to FIG. 15, the structure formed in FIG. 7 or FIG. 12 is disclosed. However, the formed string selection region is not shown in FIG. 15. For brevity, this technically shows that pattern transfer may be duplicately performed.

FIG. 15 shows a state in which a pattern is transferred to some insulating layers and conductive layers to form the first step difference group 710. Also, the pattern is not transferred to the insulating layers and conductive layers disposed under the first step difference group 710.

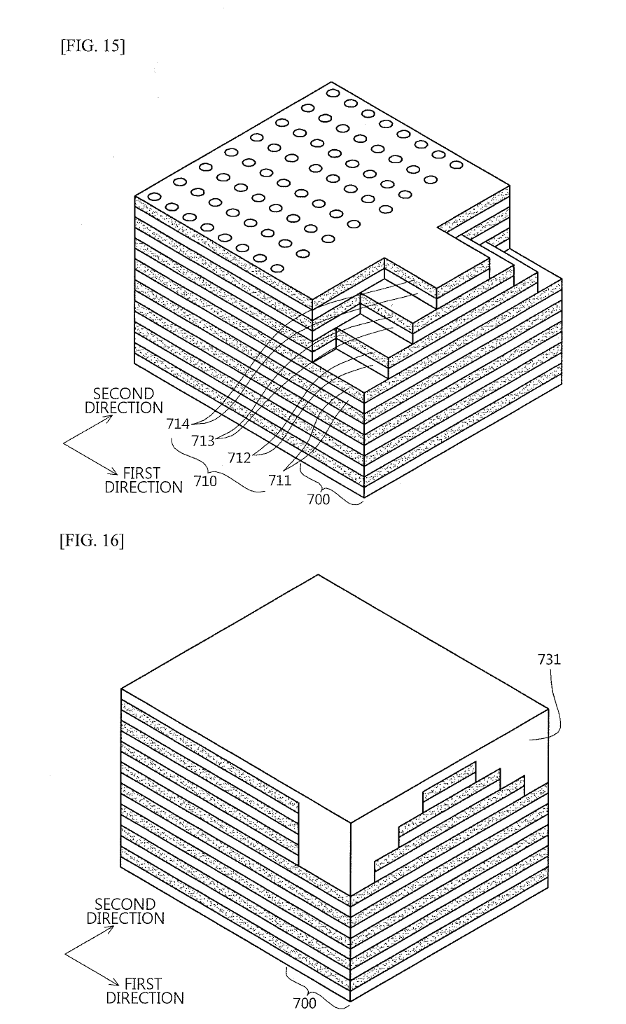

Referring to FIG. 16, a sacrificial layer 731 is formed on the structure disclosed in FIG. 15. The sacrificial layer 731 is preferably formed of an insulating material having an etch selectivity with respect to a conductive layer.

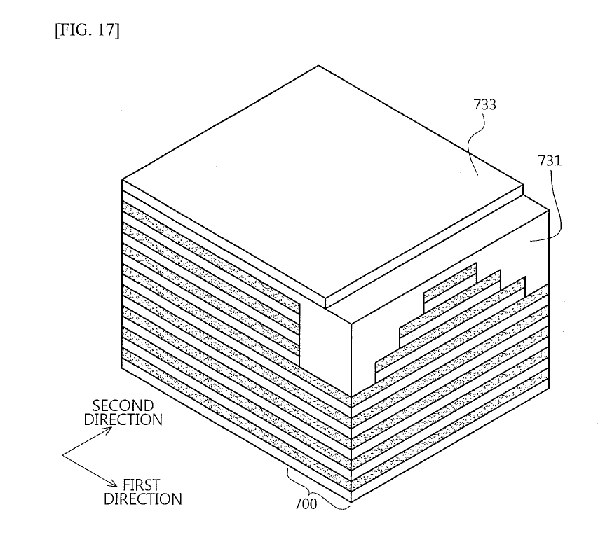

Referring to FIG. 17, a hard mask layer 733 is formed on the sacrificial layer 731. The hard mask layer 733 may be formed to cover a portion of the contact region 700.

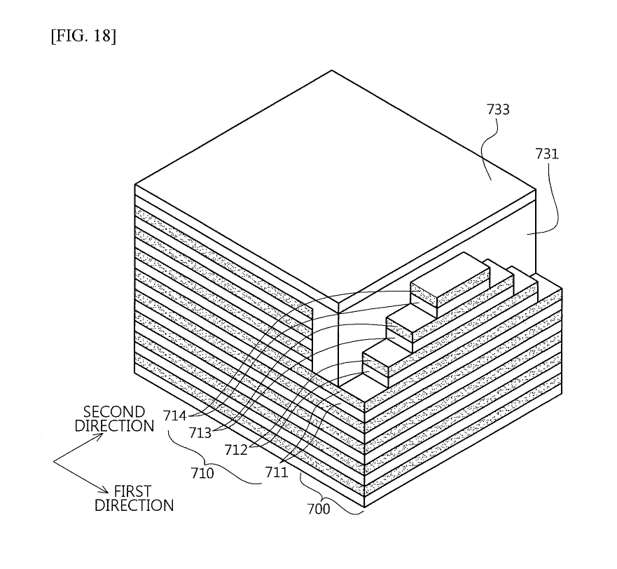

Referring to FIG. 18, the sacrificial layer 731 is removed by etching using the hard mask layer 733 as an etch mask, and a portion of the first step difference group 710 is exposed. The remaining first step difference group 710 is buried in the sacrificial layer 731 provided under the hard mask layer 733 and remains.

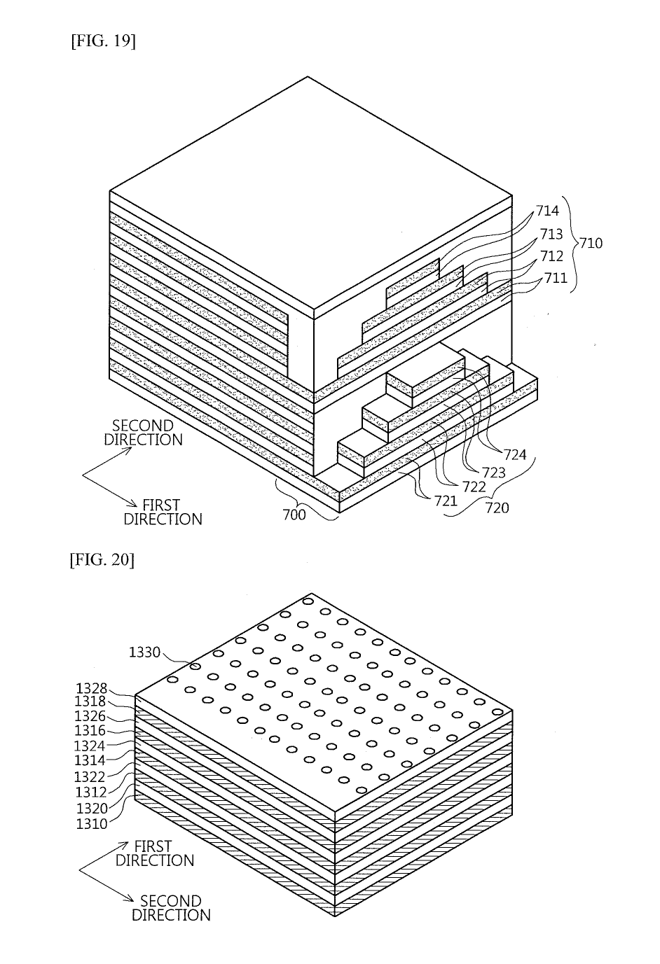

Referring to FIG. 19, the transfer of a pattern is performed on an exposed portion of the first step difference group 710. The transfer of the pattern is performed in the same manner as described in the first embodiment. The pattern is transferred to the exposed first step difference group 710 to form a second step difference group 720.

In the above-described process, a plurality of step difference groups having step differences with respect to one another may be formed. Although the present embodiment describes a technique of forming two step difference groups, it would be apparent to one skilled in the art that three or more step difference groups may be formed using a subsequent process. After forming the step difference groups, a plug forming process and an interconnection process are performed in the same manner as described in the first embodiment.

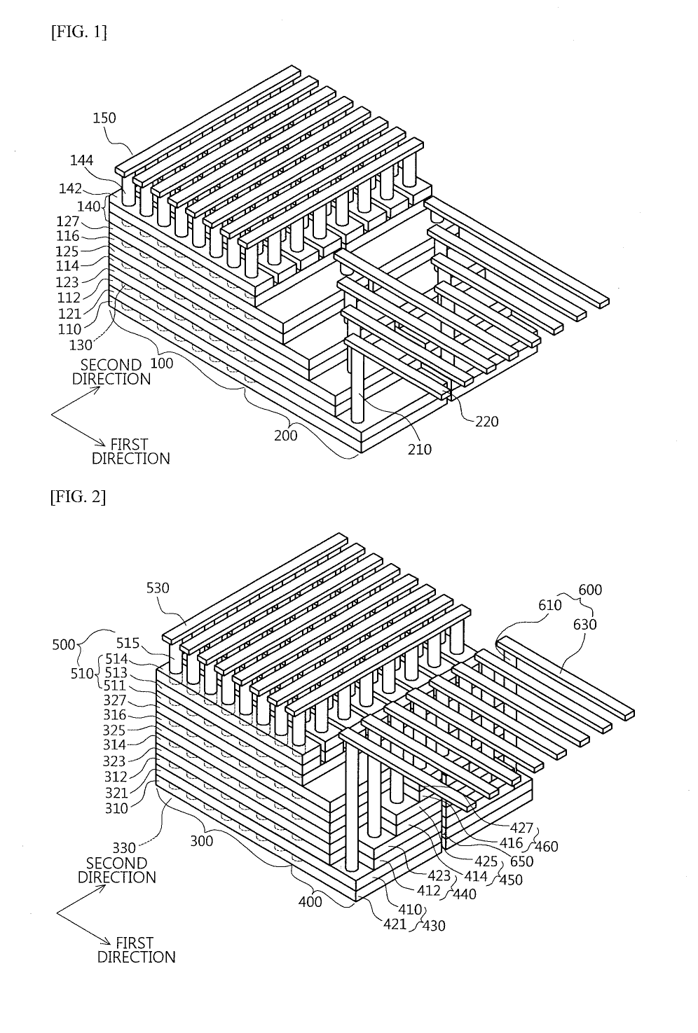

According to the above-described embodiments of the present invention, a plurality of step difference layers having step differences in a different direction from a direction in which a cell region and a contact region are disposed are disposed in the contact region. Accordingly, a higher integration density can be obtained as compared with the conventional case of FIG. 1, where step differences are formed in the same direction as a direction in which a contact region is disposed.

### Embodiment 3

FIGS. 20 through 33 are perspective views illustrating a method of fabricating a memory having a 3-dimensional structure according to a third exemplary embodiment of the present invention.

Referring to FIG. 20, preliminary etching layers 1310, 1312, 1314, and 1316 and insulating layers 1320, 1322, and 1324 are sequentially stacked on a substrate (not shown). A selective insulating layer 1326, a selective etching layer 1318, and a sacrificial layer 1328 are formed on the uppermost preliminary etching layer 1316. The insulating layers 1320, 1322, and 1324, the selective insulating layer 1326, and the sacrificial insulating layer 1328 are preferably formed of the same material. Also, a plurality of multilayered active layers 1330 are formed through the stacked insulating layers 1320, 1322, 1324, 1326, and 1328 and etching layers 1310, 1312, 1314, 1316, and 1318. The multilayered active layers 1330 are embodied by forming holes and filling the holes with poly-Si after forming the stack structure.

The preliminary etching layers 1310, 1312, 1314, and 1316 and the selective etching layer 1318 may be formed of any material having an etch selectivity with respect to the insulating layers 1320, 1322, and 1324, the selective insulating layer 1326, and the sacrificial insulating layer 1328, but the preliminary etching layers 1310, 1312, 1314, and 1316 and the selective etching layer 1318 are preferably formed of silicon nitride. Also, the insulating layers 1320, 1322, 1324, 1326, and 1328 are preferably formed of silicon oxide.

Accordingly, a first preliminary etching layer 1310, a first insulating layer 1320, a second preliminary etching layer 1312, and so on are sequentially stacked on a substrate or another layer (not shown). Also, it would be well known to one skilled in the art that the number of insulating layers 1320, 1322, and 1324 and the number of preliminary etching layers 1310, 1312, 1314, and 1316 may be changed according to embodiments.

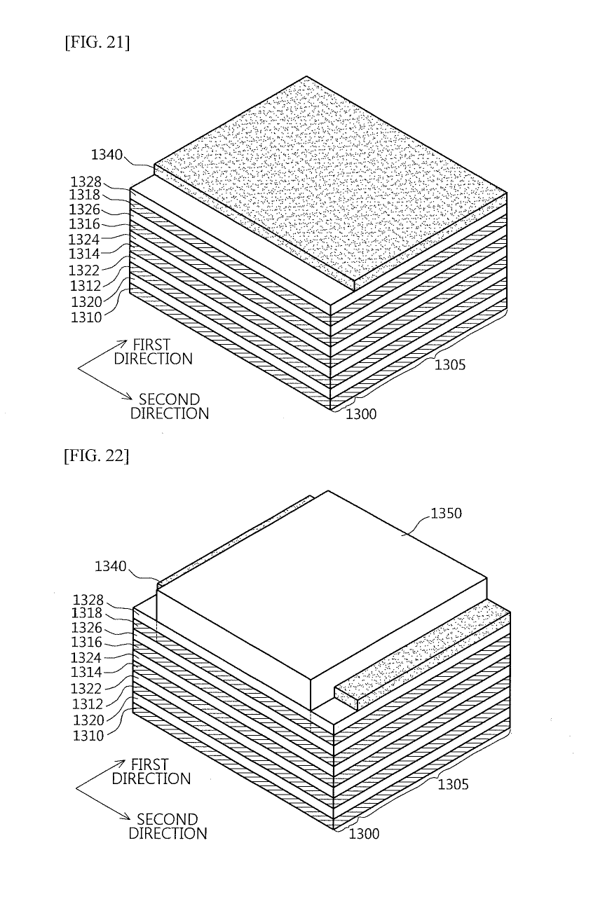

Referring to FIG. 21, a patterned hard mask layer 1340 is formed on the uppermost sacrificial insulating layer 1328. The patterned hard mask layer 1340 is formed using an ordinary photolithography process. Also, a contact region 1300 is divided from a cell region 1305 by the patterned hard mask layer 1340. That is, a region opened by the patterned hard mask layer 1340 is defined as the contact region 1300, while a region closed by the patterned hard mask layer 1340 is defined as the cell region 1305.

Referring to FIG. 22, a soft mask layer is formed on the patterned hard mask layer 1340 and the opened cell region 1300. The soft mask layer is patterned to be capable of being transferred. The soft mask layer preferably includes photoresist. The patterned soft mask layer is called a first transfer pattern 1350.

Subsequently, the sacrificial insulating layer 1328 and the selective etching layer 1318 of the contact region 1300 are etched using the first transfer pattern 1350 and the hard mask layer 1340 as an etch mask. By sequentially etching the sacrificial insulating layer 1328 and the selective etching layer 1318, the sacrificial insulating layer 1328 and the selective etching layer 1318 have the same profile as the first transfer pattern 1350, and a portion of the selective insulating layer 1326 disposed under the selective etching layer 1318 is exposed.

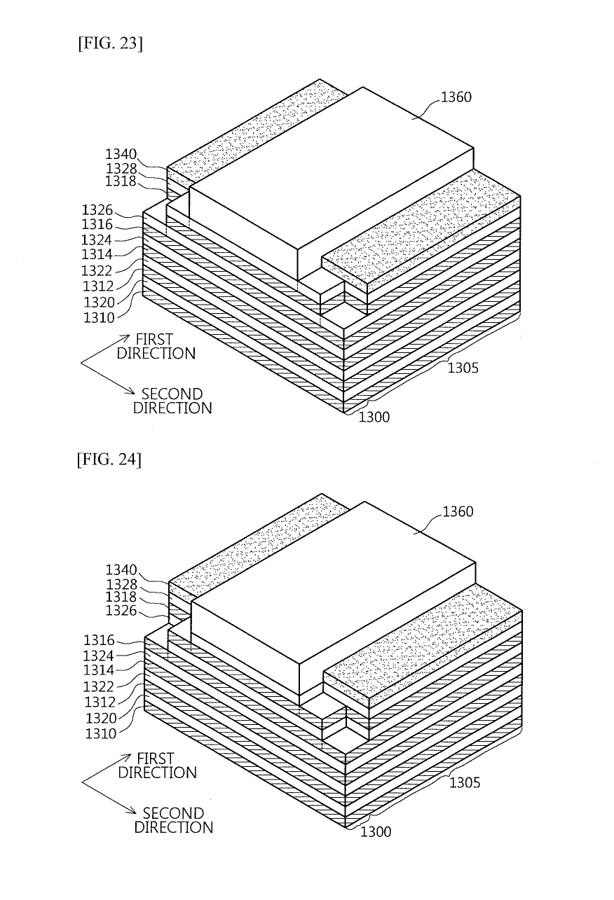

Referring to FIG. 23, a reduction process is performed on the first transfer pattern 1350, thereby forming a second transfer pattern 1360. The reduction process, which is referred to as photoresist shrink or photoresist slimming, is performed to reduce the size of the formed photoresist. A reduction in the photoresist is attained by exposing the photoresist to a reactive plasma gas. However, the reactive plasma gas may be differently selected according to the composition of a photoresist pattern.

A portion of the sacrificial insulating layer 1328 is exposed under the second transfer pattern 1360 formed using the reduction process. Also, due to the process described with reference to FIG. 22, a portion of the selective insulating layer 1326 is exposed.

Thereafter, the exposed portion of the surface of the sacrificial insulating layer 1328 and the exposed portion of the selective insulating layer 1326 are etched, thereby exposing a portion of the selective etching layer 1318 and a partial surface of the fourth preliminary etching layer 1316. Accordingly, the sacrificial insulating layer 1328 has the same profile as the second transfer pattern 1360, and the selective etching layer 1318 and the selective insulating layer 1326 have the same profile as the first transfer pattern 1350.

Referring to FIG. 24, the opened selective etching layer 1318 and the fourth preliminary etching layer 1316 are etched. Due to the etching, the selective etching layer 1318 has the same profile as the second transfer pattern 1360, and the fourth preliminary etching layer 1316 has the same profile as the first transfer pattern 1350.

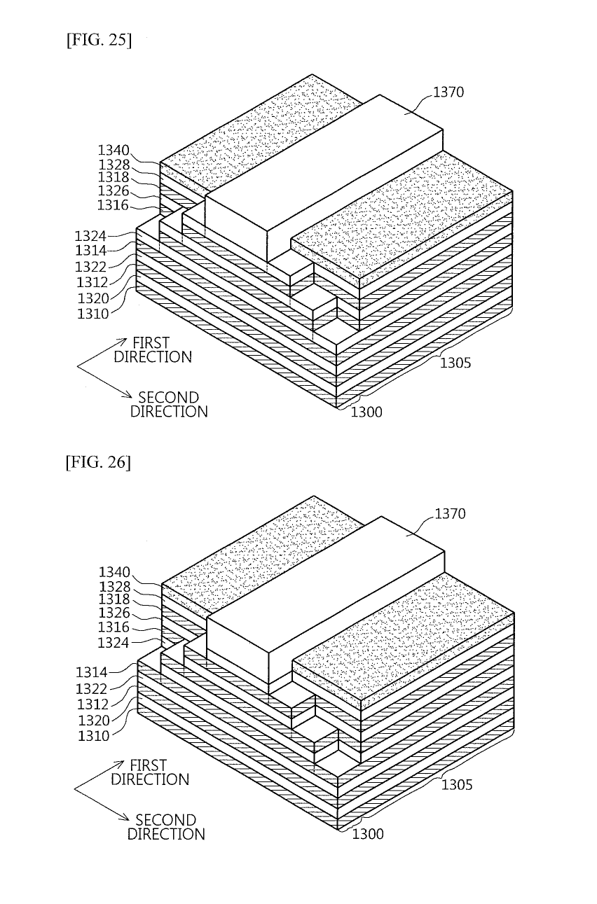

Referring to FIG. 25, a reduction process is performed on the second transfer pattern 1360, thereby forming a third transfer pattern 1370.

Furthermore, the opened sacrificial insulating layer 1328, selective insulating layer 1326, and third insulating layer 1324 are etched. Due to the etching, the sacrificial insulating layer 1328 has the same profile as the third transfer pattern 1370, and a portion of the underlying selective etching layer 1318 is exposed.

The exposed selective etching layer 1318 has the same profile as the second transfer pattern 1360. Also, the selective insulating layer 1326 has the same profile as the second transfer pattern 1360, and a portion of the underlying fourth preliminary etching layer 1316 is exposed. Due to the etching, the third insulating layer 1324 has the same profile as the first transfer pattern 1350, and a portion of the underlying third preliminary etching layer 1314 is exposed.

Referring to FIG. 26, the selective etching layer 1318, the fourth preliminary etching layer 1316, and the third preliminary etching layer 1314 exposed by the etching process described with reference to FIG. 25 are etched.

Due to the etching, the selective etching layer 1318 has the same profile as the sacrificial insulating layer 1328 and the third transfer pattern 1370. Also, the fourth preliminary etching layer 1316 has the same profile as the selective insulating layer 1326 and has the same profile as the second transfer pattern 1360.

The third preliminary etching layer 1314 has the same profile as the third insulating layer 1324 and has the same profile as the first transfer pattern 1350. As a result, a portion of the surface of the second insulating layer 1322 disposed under the third preliminary etching layer 1314 is exposed.

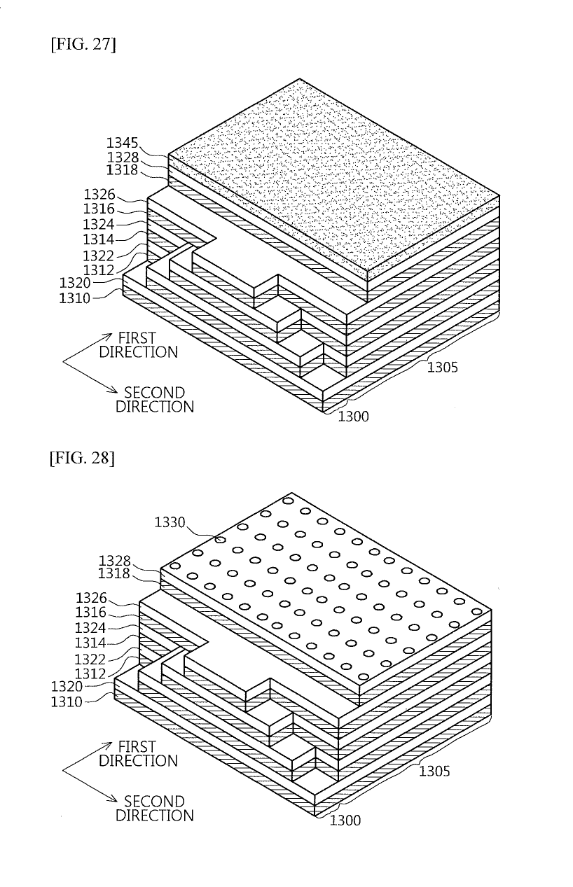

Referring to FIG. 27, the remaining transfer pattern 1370 and hard mask layer 1340 are removed, and a photoresist pattern 1345 is formed on the substrate. The photoresist pattern 1345 is obtained using an ordinary lithography process. Thereafter, an etching process is performed using the formed photoresist pattern 1345 as an etch mask. Thus, the exposed sacrificial insulating layer 1328, selective insulating layer 1326, third insulating layer 1324, and second insulating layer 1322 are etched. In particular, the sacrificial insulating layer 1328 is completely removed from the contact region 1300, and the remaining insulating layers 1326, 1324, and 1322 are pattern-transferred to underlying layers. Next, the exposed selective etching layer 1318, fourth preliminary etching layer 1316, third preliminary etching layer 1314, and second preliminary etching layer 1312 are etched. Accordingly, a structure shown in FIG. 27 is formed through two etching processes. In particular, the sacrificial insulating layer 1328 and the selective etching layer 1318 are recessed from the contact region 1300 toward the cell region 1305.

The respective etching layers and insulating layers have staircase-type step differences due to the transfer of patterns.

Referring to FIG. 28, the photoresist pattern formed on the sacrificial insulating layer 1328 is removed. By removing the photoresist pattern, a top surface of the sacrificial insulating layer 1328 is exposed. Also, end portions of the multilayered active layers 1330 formed through a plurality of layers are also exposed.

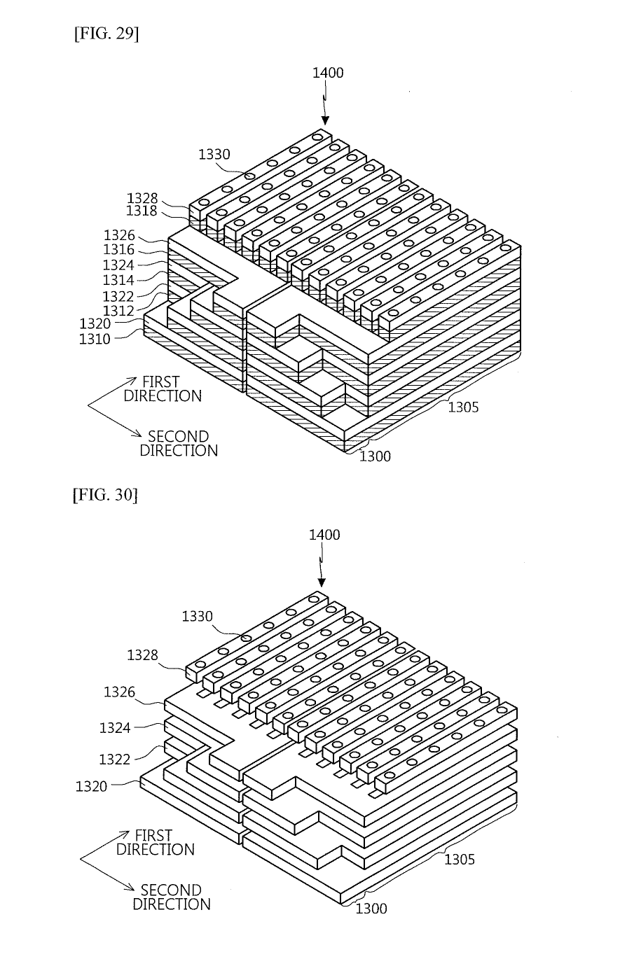

Referring to FIG. 29, the cell region 1305 extending in a first direction is patterned using selective etching. That is, a central portion of the structure shown in FIG. 28 is etched in the first direction, and the cell region 1305 is etched to partition the multilayered active layers 1330 aligned in the first direction. The etching process is performed until the lowermost first preliminary etching layer 1310 is patterned. Thus, a string region 1400 of the memory is defined.

Also, a step difference structure forming the contact region 1300 is not etched but maintains its original shape. However, the central portion of the structure shown in FIG. 28 is etched to form a symmetrical step difference structure.

Referring to FIG. 30, the structure shown in FIG. 29 is wet etched. Due to the wet etching, the selective etching layer 1318 and the preliminary etching layers 1310, 1312, 1314, and 1316 are removed. That is, since the selective etching layer 1318 and the preliminary etching layers 1310, 1312, 1314, and 1316 have an etch selectivity with respect to the disclosed insulating layers 1320, 1322, 1324, 1326, and 1328, the selective etching layer 1318 and the preliminary etching layers 1310, 1312, 1314, and 1316 are removed by selecting an appropriate etchant. Accordingly, the multilayered active layers 1330, the sacrificial insulating layer 1328, the selective insulating layer 1326, and the plurality of insulating layers 1324, 1322, and 1320 remain, and a portion of a side surface of the multilayered active layer 1330 is exposed.

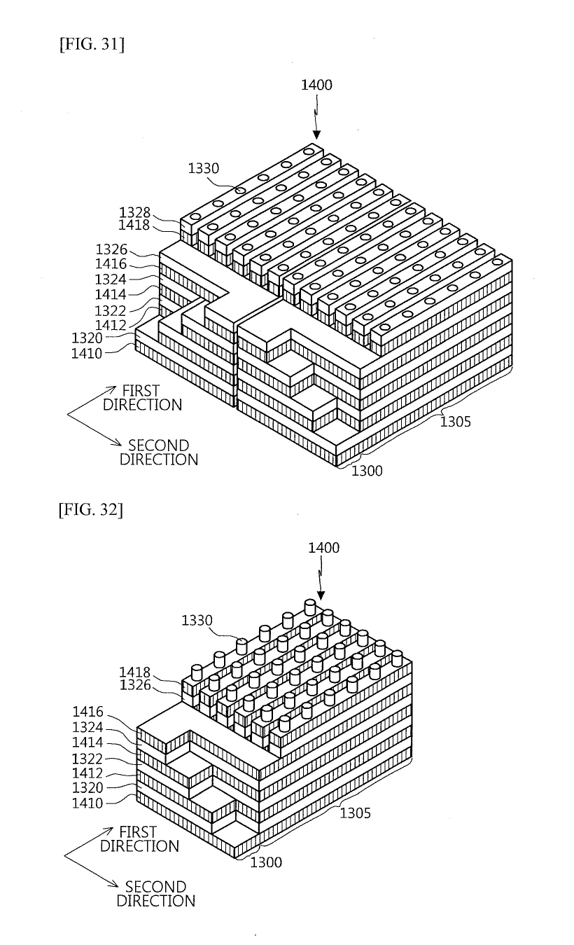

Referring to FIG. 31, an ONO layer is deposited on the exposed side surface of the multilayered active layer 1330. Thereafter, a conductive layer is formed on the ONO layer, and the conductive layer filled between the string regions 1400 is removed. Accordingly, spaces between the insulating layers 1328, 1326, 1324, 1322, and 1320 formed in contact with the same multilayered active layer 1330 are filled with the ONO layer and the conductive layer. The conductive layer is preferably formed of tungsten.

Accordingly, the conductive layers 1410, 1412, 1414, 1416, and 1418 are formed instead of the selective etching layer and the preliminary etching layers. That is, the first through fourth conductive layers 1410 to 1416 are sequentially formed, and the selective conductive layer 1418 is formed in the string region 1400.

Referring to FIG. 32, a blanket etching process is performed on the structure shown in FIG. 31. Due to the blanket etching, the exposed insulating layers 1328, 1326, 1324, 1322, and 1320 are removed. FIG. 32 illustrates a right region separated from the structure shown in FIG. 31.

Referring to FIG. 32, the uppermost sacrificial insulating layer is removed, and portions of the plurality of multilayered active layers 1330 formed through the uppermost sacrificial insulating layer are exposed. Also, the selective insulating layer 1326 recessed toward the cell region 1305 is patterned, and the partially exposed third insulating layer 1324, second insulating layer 1322, and first insulating layer 1320 are removed. As a result, partial surfaces of the selective conductive layer 1418, fourth conductive layer 1416, third conductive layer 1414, second conductive layer 1412, and first conductive layer 1410 are exposed.

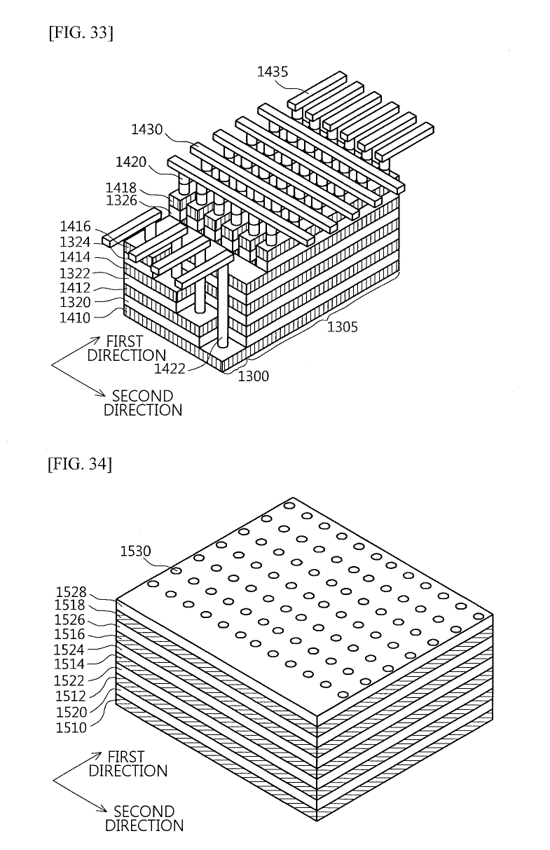

Referring to FIG. 33, selective plugs 1420 are formed on the exposed portions of the multilayered active layers 1330, and connection plugs 1422 are formed on the exposed conductive layers 1416, 1414, 1412, and 1410. Also, the selective plugs 1420 are respectively connected to first interconnection groups 1430, and the connection plugs 1422 are connected to the second interconnection groups 1435. Naturally, a memory structure is buried in an interlayer insulating layer before forming the plugs 1420 and 1422 and the interconnection groups 1430 and 1435. Accordingly, the formation of the plugs 1420 and 1422 is attained by selectively etching the interlayer insulating layer and burying a conductive material.

As described above, in the present embodiment, the string region 1400 extends in the first direction. Also, step differences are formed in a second direction perpendicular to the first direction and electrically connected to interconnections through conductive layers exposed on the step differences. Accordingly, a higher integration density can be obtained as compared with a case in which step differences are formed in the same direction as the first direction in which strings are aligned.

### Embodiment 4

FIGS. 34 through 41 are perspective views illustrating a method of fabricating a memory according to a fourth exemplary embodiment of the present invention.

Referring to FIG. 34, preliminary etching layers 1510, 1512, 1514, and 1516 and insulating layers 1520, 1522, and 1524 are sequentially stacked on a substrate (not shown). Also, a selective insulating layer 1526, a selective etching layer 1518, and a sacrificial insulating layer 1528 are formed on the uppermost preliminary etching layer 1516. The insulating layers 1520, 1522, and 1524, the selective insulating layer 1526, and the sacrificial insulating layer 1528 are preferably formed of the same material. Also, a plurality of multilayered active layers 1530 are formed through the stacked insulating layers 1520, 1522, 1524, 1526, and 1528 and etching layers 1510, 1512, 1514, 1516, and 1518. After forming the stack structures, the multilayered active layers 1530 are formed by forming holes and filling the holes with poly-Si.

Although the preliminary etching layers 1510, 1512, 1514, and 1516 and the selective etching layer 1518 may be formed of any material having an etch selectivity with respect to the insulating layers 1520, 1522, and 1524, the selective insulating layer 1526, and the sacrificial insulating layer 1528, the preliminary etching layers 1510, 1512, 1514, and 1516 and the selective etching layer 1518 are preferably formed of silicon nitride. Also, the insulating layers 1520, 1522, 1524, 1526, and 1528 are preferably formed of silicon oxide.

Accordingly, a first preliminary etching layer 1510, a first insulating layer 1520, a second preliminary etching layer 1512, and so on are sequentially stacked on a substrate or another layer (not shown). Also, the number of insulating layers 1520, 1522, and 1524 and the number of preliminary etching layers 1510, 1512, 1514, and 1516 may be changed as shown in FIG. 20 according to embodiments.

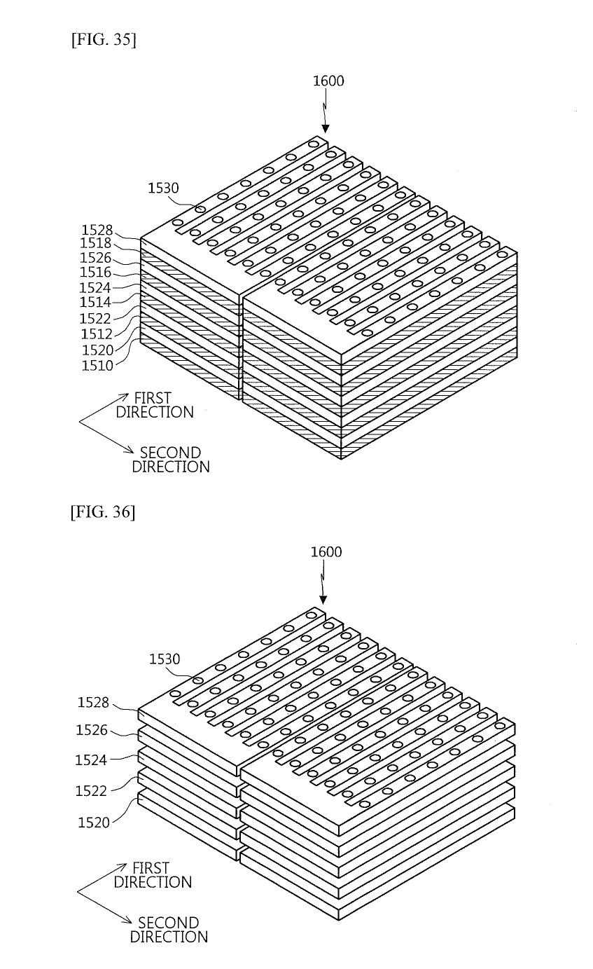

Referring to FIG. 35, a structure disclosed in FIG. 34 is selectively etched to define a string region 1600, and a central portion of the structure is etched to form two symmetrical structures. Accordingly, the string region 1600 is structured to extend in a first direction and is spaced apart from adjacent string regions in a second direction.

Referring to FIG. 36, a structure shown in FIG. 35 is wet etched. Due to the wet etching, the selective etching layer 1518 and the preliminary etching layers 1510, 1512, 1514, and 1516 are removed. That is, since the selective etching layer 1518 and the preliminary etching layers 1510, 1512, 1514, and 1516 have an etch selectivity with respect to the disclosed insulating layers 1520, 1522, 1524, 1526, and 1528, the selective etching layer 1518 and the preliminary etching layers 1510, 1512, 1514, and 1516 are removed by selecting an appropriate etchant. As a result, the multilayered active layers 1530, the sacrificial insulating layer 1528, the selective insulating layer 1526, and the plurality of insulating layers 1520, 1522, and 1524 remain, and portions of side surfaces of the multilayered active layers 1530 are exposed.

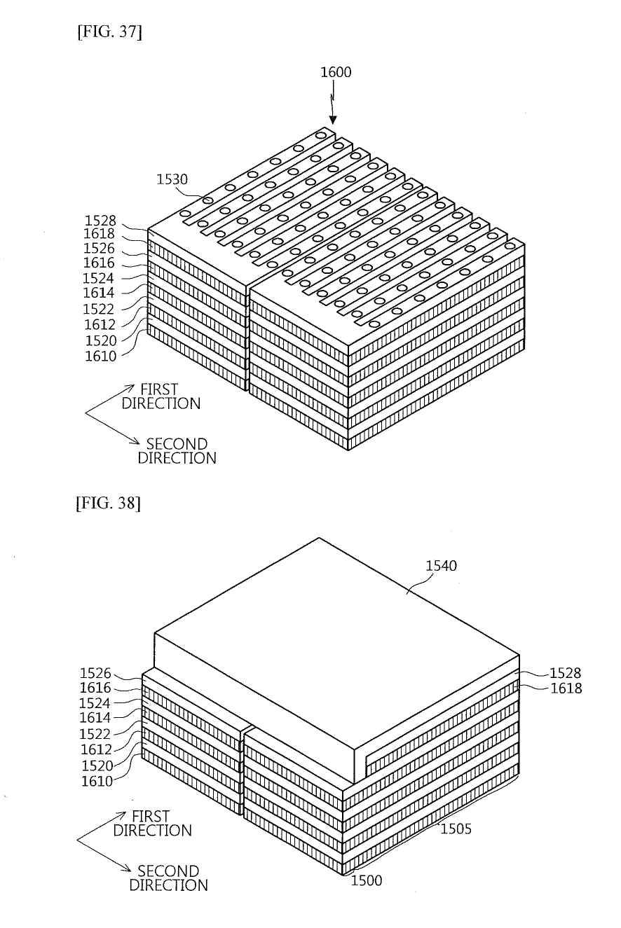

Referring to FIG. 37, an ONO layer is deposited on the exposed side surfaces of the multilayered active layers 1530. Afterwards, a conductive layer is formed on the ONO layer, and the conductive layer filled between the string regions 1600 is removed. Accordingly, spaces between the insulating layers 1520, 1522, 1524, 1526, and 1528 formed in contact with the same multilayered active layers 1530 are filled with the ONO layer and conductive layers 1610, 1612, 1614, 1616, and 1618. The conductive layers 1610, 1612, 1614, 1616, and 1618 are preferably formed of tungsten. Accordingly, the conductive layers 1610, 1612, 1614, 1616, and 1618 are formed instead of the selective etching layer 1518 and the preliminary etching layers 1510, 1512, 1514, and 1516. That is, first through fourth conductive layers 1610 to 1616 are sequentially formed, and a selective conductive layer 1618 is formed in the string region 1600.

Referring to FIG. 38, an upper portion of the structure including the ONO layer and the conductive layer 1618 is partially etched, and a hard mask layer 1540 is formed. That is, the sacrificial insulating layer 1528 and the selective conductive layer 1618 recessed toward the cell region 1505 are formed by partially etching the sacrificial insulating layer 1528 and the selective conductive layer 1618, and the hard mask layer 1540 is formed to cover the formed sacrificial insulating layer 1528 and selective conductive layer 1618. The hard mask layer 1540 is formed to open a contact region 1500.

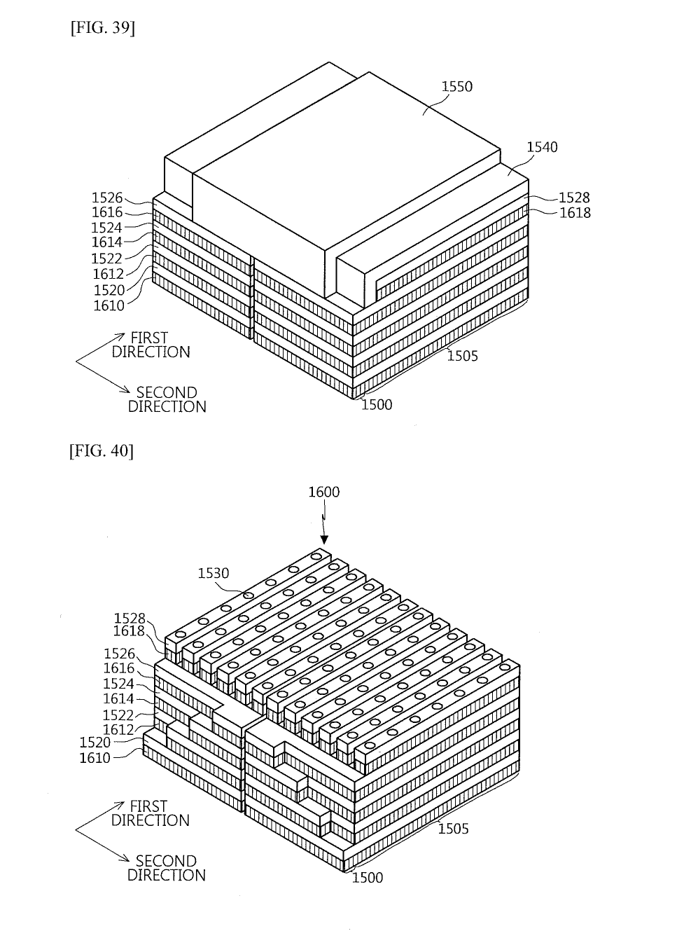

Referring to FIG. 39, a first transfer pattern 1550 is formed in an upper portion of the hard mask layer 1540 and an upper portion of the contact region 1500. After the first transfer pattern 1550 is formed, a transfer pattern formed using sequential etching and formation of a transfer pattern is transmitted to the underlying layer. The resultant structure is disclosed in FIG. 40.

That is, as described in the third embodiment with reference to FIGS. 22 through 27, the first conductive layer 1610, the first insulating layer 1520, the second conductive layer 1612, the second insulating layer 1522, the third conductive layer 1614, the third insulating layer 1524, the fourth conductive layer 1616, and the selective insulating layer 1526 are sequentially formed to have predetermined step differences. Also, the conductive layers 1610, 1612, 1614, and 1616 and the insulating layers 1520, 1522, 1524, and 1526 form pairs and have the same profiles, respectively.

Referring to FIG. 40, the transfer pattern and the hard mask layer are removed. Accordingly, the string region 1600 and the contact region 1500 are exposed.

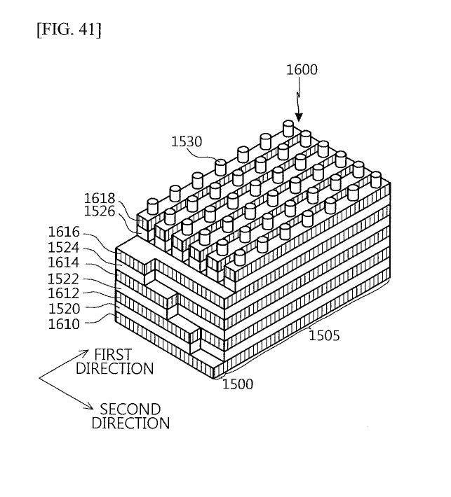

Referring to FIG. 41, blanket etching is performed on the structure shown in FIG. 40. The sacrificial insulating layer 1528 formed on the string region 1600 is removed by blanket etching. Also, the selective conductive layer 1618 disposed under the sacrificial insulating layer 1528 is opened, and the selective insulating layer 1526 disposed under the selective conductive layer 1618 is etched to have the same profile as the selective conductive layer 1618.

The exposed insulating layers are removed using blanket etching. Accordingly, the selective conductive layer 1618 and the first through fourth conductive layers 1610, 1612, 1614, and 1616 are opened in the contact region 1500. While the conductive layers 1610, 1612, 1614, 1616, and 1618 are opened, portions of the multilayered active layers 1530 formed through the structure protrude from the selective conductive layer 1618, which is shown in FIG. 42.

In addition, formation of plugs for forming a memory and formation of bit lines and word lines are the same as described in the third embodiment with reference to FIG. 33.

In the present embodiment, the string region extends in a first direction. Also, step differences are formed in a second direction perpendicular to the first direction and electrically connected to interconnections through conductive layers exposed on the step differences. Accordingly, a higher integration density can be obtained as compared with a case in which step differences are formed in the same direction as the first direction in which strings are aligned.

Therefore, according to the present invention, a cell region is divided from a contact region depending on the presence or absence of step differences. The step differences are made in a direction perpendicular to a direction in which strings are formed. Accordingly, a higher integration density can be obtained as compared with the conventional art in which step differences are formed in the same direction as a direction in which strings are formed. In particular, a plurality of memory cells can be formed in one string by removing an etching layer, forming an ONO layer, and forming a conductive layer.

Furthermore, in the present invention, a lowermost layer of a plurality of multilayered layers is illustrated as a conductive layer for brevity. Thus, other kinds of layers can be disposed under the conductive layer, and a first conductive layer disposed as the lowermost layer can be used to control operations of a cell transistor constituting a memory, along with a string selection region.

While the invention has been shown and described with reference to m certain exemplary embodiments thereof, it will be understood by those skilled in the art that various changes in form and details may be made therein without departing from the spirit and scope of the invention as defined by the appended claims.

1. A flash memory comprising:
a cell region having insulating layers and electrode layers alternately formed, the cell region having multilayered plugs formed through the insulating layers and the electrode layers; and
a contact region extending from the cell region in a first direction, the contact region having a step difference in a second direction perpendicular to the first direction.

2. The memory of claim 1, wherein each of the multilayered plugs has an oxide-nitride-oxide (ONO) structure toward an outer portion thereof, and a central portion of each of the multilayered plugs is formed of polycrystalline silicon (poly-Si).

3. The memory of claim 1, wherein the contact region includes a plurality of step difference layers having smaller widths toward an upper portion of the contact region.

4. The memory of claim 3, wherein each of the step difference layers includes the insulating layer and the electrode layer, and the insulating layer and the electrode layer constituting one step difference layer have the same profile.

5. The memory of claim 1, further comprising a bit line interconnection region disposed on the cell region and electrically connected to a bit line.

6. The memory of claim 5, wherein the bit line interconnection region comprises:
a patterned string selection region extending in the first direction; and
the bit line electrically connected to the string selection region.

7. The memory of claim 1, wherein the contact region has a plurality of step difference groups, each of which has a step difference with respect to adjacent step difference groups.

8. The memory of claim 7, wherein the step difference groups have smaller widths toward an upper portion of the contact region.

9. The memory of claim 7, wherein the step difference groups have step differences with respect to one another in the first direction, and step difference layers forming one step difference group have step differences with respect to one another in the second direction.

10. A method of fabricating a flash memory, comprising the steps of:
sequentially stacking insulating layers and electrode layers and forming multilayered plugs through the insulating layers and the electrode layers;
forming a selective insulating layer and a selective conductive layer on an uppermost electrode layer and forming string plugs through the selective insulating layer and the selective conductive layer to be electrically connected to the multilayered plugs;
forming a string selection region by selectively etching the selective insulating layer and the selective conductive layer and defining a cell region and a contact region extending in a first direction; and
forming a plurality of step difference layers by performing sequential pattern transfer on the contact region, the plurality of step difference layers having step differences in a second direction perpendicular to the first direction.

11. The method of claim 10, further comprising, after forming the plurality of step difference layers, forming a trench to halve the cell region and the contact region.

12. The method of claim 10, wherein the multilayered plugs are formed in the cell region.

13. The method of claim 10, wherein the string selection region includes a pattern formed using the selective etching process, the pattern extending in the first direction.

14. The method of claim 13, wherein the step of defining the cell region and the contact region comprises forming a trench to halve the cell region and the contact region.

15. The method of claim 10, further comprising, after forming the plurality of step difference layers, etching the string selection region to form a patterned string selection region extending in the first direction and forming a trench to halve the cell region and the contact region.

16. A flash memory comprising a contact region connected to a cell region including a cell transistor and electrically connected to a word line, the contact region including a plurality of step difference layers having step differences formed in a different direction from a direction in which the cell region and the contact region are disposed.

17. The memory of claim 16, wherein the contact region is disposed in a first direction from the cell region, and the step difference layers have step differences in a second direction perpendicular to the first direction and have smaller areas toward an upper portion of the contact region.

18. The memory of claim 17, wherein each of the step difference layers includes an insulating layer and a conductive layer, and the insulating layer and the conductive layer constituting one step difference layer have the same profile.

19. A method of fabricating a memory, comprising the steps of:
alternately forming preliminary etching layers and insulating layers;
sequentially forming a selective insulating layer, a selective etching layer, and a sacrificial insulating layer on an uppermost preliminary etching layer;
forming multilayered active layers through the preliminary etching layers, the insulating layers, the selective insulating layer, the selective etching layer, and the sacrificial insulating layer, the multilayered active layers disposed in a first direction;
defining a contact region and a cell region having the multilayered active layers;
forming a step difference in a second direction perpendicular to the first direction by performing pattern transfer on the contact region;
forming a plurality of string regions by selectively etching the cell region after performing the pattern transfer, the plurality of string regions extending in the first direction; and
removing the selective etching layer and the preliminary etching layers and forming an ONO layer and conductive layers.

20. The method of claim 19, wherein the defining of the contact region and the cell region comprises forming a hard mask layer on the sacrificial insulating layer to cover the multilayered active layers.

21. The method of claim 19, wherein the removing of the sacrificial etching layer and the preliminary etching layers is performed using a wet etching process, and the insulating layers, the selective insulating layer, the sacrificial insulating layer, and the multilayered active layers remain due to the wet etching process.

22. The method of claim 19, wherein the forming of the ONO layer and the conductive layers comprises forming the conductive layer to fill spaces between the insulating layers and forming a selective conductive layer to fill a space between the sacrificial insulating layer and the selective insulating layer.

23. The method of claim 22, further comprising, after the forming of the ONO layer and the conductive layers, etching the exposed sacrificial insulating layer, selective insulating layer, and insulating layers.

24. The method of claim 23, wherein, due to the etching of the exposed sacrificial insulating layer, selective insulating layer, and insulating layers, the sacrificial insulating layer is removed, and the selective insulating layer has the same profile as the selective conductive layer.

25. A method of fabricating a memory, comprising the steps of:
alternately forming preliminary etching layers and insulating layers;
sequentially forming a selective insulating layer, a selective etching layer, and a sacrificial insulating layer on an uppermost preliminary etching layer;
forming multilayered active layers through the preliminary etching layers, the insulating layers, the selective insulating layer, the selective etching layer, and the sacrificial insulating layer, the multilayered active layers disposed in a first direction;
forming string regions by etching regions in which the multilayered active layers are formed, in the first direction;
removing the selective etching layer and the preliminary etching layers and forming an ONO layer and conductive layers on side surfaces of the multilayered active layers;
defining a contact region and a cell region including the regions in which the multilayered active regions are formed and which are etched in the first direction;
forming step differences in a second direction perpendicular to the first direction by performing pattern transfer on the contact region; and
removing the exposed sacrificial insulating layer using a blanket etching process and removing the selective insulating layer and the insulating layers exposed on the step differences to expose the conductive layers.

26. The method of claim 25, wherein the removing of the selective etching layer and the preliminary etching layers is performed using a wet etching process, and the insulating layers, the selective insulating layer, the sacrificial insulating layer, and the multilayered active layers remain due to the wet etching process.

27. The method of claim 25, wherein the forming of the ONO layer and the conductive layers comprises forming the conductive layers to fill spaces between the insulating layers and forming a selective conductive layer to fill a space between the sacrificial insulating layer and the selective insulating layer.

28. The method of claim 27, wherein, due to the removing of the sacrificial insulating layer, the selective insulating layer has the same profile as the selective conductive layer.
